(19) United States
(12) Patent Application Publication
(10) Pub. No.: US 2025/0004067 A1
(43) Pub. Date: Jan. 2, 2025

(54) DEVICE FOR MEASURING A POWER CURRENT DELIVERED BY A POWER FET

(71) Applicant: STMicroelectronics International N.V., Geneva (CH)

(72) Inventors: Philippe Bienvenu, Saint-Maximin (FR); Antonio Calandra, Saint Maximin (FR); Julia Castellan, Trets (FR)

(21) Appl. No.: 18/677,834

(22) Filed: May 29, 2024

(30) Foreign Application Priority Data
Jun. 28, 2023 (FR) 2306826

(51) Int. Cl. G01R 31/40

(52) U.S. Cl. CPC G01R 31/40

(57) ABSTRACT

The present disclosure relates to a device for measuring a power current supplied by a main power FET. The device includes a current measurement power FET coupled with the main FET; first and second FETs, the gates of which are coupled with each other, the first FET is coupled with the current measurement FET, in which a source/drain terminal of the second FET is coupled with a source/drain terminal of the first FET, or a source/drain terminal of the second FET is coupled with a source/drain terminal of the main FET or to a voltage source or load external to the device, and source/drain terminals of the first and second FETs are coupled with each other.

### CROSS-REFERENCE TO RELATED APPLICATIONS

This application claims priority to French Application No. 23/06826, filed on Jun. 28, 2023, which application is hereby incorporated by reference in its entirety.

### TECHNICAL FIELD

The present description relates generally to a device for measuring a power current supplied by a power FET.

### BACKGROUND

Measuring the current supplied by a power FET driving an electrical load can be performed, in particular, to effectively drive the load, diagnose a problem with the load, or protect the load and the circuit to which it belongs.

To measure the current supplied by a power FET driving an electrical load, another power FET dedicated to this measurement can be used, coupled in a branch of the circuit parallel to that, including the main power FET.

To ensure that the current supplied by the measurement FET is very low compared with the current supplied by the main power FET, the measurement FET is designed to occupy a much smaller semiconductor surface area than that occupied by the main power FET. The value of the ratio between the semiconductor surface area of the main power FET and that of the measurement FET can be selected in particular according to the functions to be fulfilled by the power circuit in which the main power transistor is located and the desired values for the power current.

The features of the measurement FET, in particular the form factor, can be optimized in each of its regions to avoid the problems encountered with power transistors with too small dimensions (difference in dynamic behavior from that expected, change in transistor response as a function of operating temperature), which are due in particular to edge effects and variations in the form factor of the edge and corner cells of the transistor.

### SUMMARY

It would be advantageous to offer a device for measuring a power current supplied by a main power FET without existing solutions' drawbacks.

A particular embodiment addresses at least some of these problems and provides a device for measuring a power current intended to be supplied by a main power FET, comprising at least a current measurement power FET comprising a first source or drain terminal configured to be coupled with a first source or drain terminal of the main power FET; first and second FETs, the gates of which are electrically coupled with each other, a first source or drain terminal of the first FET being coupled with a second source or drain terminal of the current measurement power FET, wherein a first source or drain terminal of the second FET is coupled with the first source or drain terminal of the first FET, or wherein the first source or drain terminal of the second FET is configured to be coupled with a second source or drain terminal of the main power FET or with a voltage source or a load external to the device, and second source or drain terminals of the first and second FETs are electrically coupled with each other.

According to a particular embodiment, a semiconductor surface of the current measurement power FET and channel widths of the first and second FETs are so that the value of a ratio between a charging current intended to be supplied at the second source or drain terminal of the main power FET and an output current intended to be supplied at the second source or drain terminal of the first FET differs from that of a ratio between a semiconductor surface of the main power FET and the semiconductor surface of the current measurement power FET.

According to a particular embodiment, the current measurement power FET is of the VDMOSFET type, and the first and second FETs are of the MOSFET type.

According to a particular embodiment, the first and second FETs have different channel widths.

According to a particular embodiment, the device further includes a comparator having a first input configured to be coupled with the second source or drain terminal of the main power FET, a second input coupled with the second source or drain terminal of the current measurement power FET, and an output coupled with the gates of the first and second FETs.

According to a particular embodiment, the device further includes at least one third FET, the gate of which is coupled with the gates of the first and second FETs, and a first source or drain terminal, which is coupled with the first source or drain terminal of the first FET or with the second source or drain terminal of the main power FET.

According to a particular embodiment, the device further includes a fourth FET, a first source or drain terminal of which is coupled with the second source or drain terminal of the current measurement power FET, and a second source or drain terminal of which is coupled with the first source or drain terminal of the first FET; a comparator having a first input coupled with the second source or drain terminal of the current measurement power FET, a second input configured to be coupled with the second source or drain terminal of the main power FET, and an output coupled with the gate of the fourth FET.

According to a particular embodiment, the first and second FETs are mounted as a current mirror.

According to a particular embodiment, the first and second FETs are P-type. The gates of the first and second FETs are coupled with the second source or drain terminal of the first FET, and the first source or drain terminal of the second FET is coupled with the first source or drain terminal of the first FET.

According to a particular embodiment, the first and second FETs are of the N-type; the gates of the first and second FETs are coupled with the first source or drain terminal of the first FET; the second source or drain terminals of the first and second FETs are electrically coupled with each other.

A particular embodiment provides a power control circuit for controlling an electrical load, comprising at least a main power FET comprising a first source or drain terminal configured to be coupled with an electrical power source and a second source or drain terminal configured to be coupled with a terminal of the electrical load; a device for measuring a power current supplied by the main power FET as described above.

According to a particular embodiment, the main power FET and the current measurement power FET are of the same conductivity type.

A particular embodiment provides a method for producing a power control circuit for controlling an electrical load, comprising at least a production of a main power FET comprising a first source or drain terminal configured to be coupled with an electrical power source and a second source or drain terminal configured to be coupled with a terminal of the electrical load, and of a device for measuring a power current supplied by the main power FET as described above.

According to a particular embodiment, the method further includes, before the production of the main power FET and of the device for measuring a power current supplied by the main power FET, a step of determining a semiconductor surface of the current measurement power FET and channel widths of the first and second FETs of the device for measuring a power current supplied by the main power FET so that the value of a ratio between a charging current intended to be supplied at the second source or drain terminal of the main power FET and an output current intended to be supplied at the second source or drain terminal of the first FET differs from that of a ratio between a semiconductor surface of the main power FET and the semiconductor surface of the current measurement power FET; and wherein at least the current measurement power FET and the first and second FETs of the device are then produced according to the previously determined semiconductor surface of the current measurement power FET and channel widths of the first and second FETs.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 schematically illustrates an example device for measuring a power current supplied by a main power FET, according to a first embodiment;

FIG. 2 schematically illustrates an alternative implementation of the device for measuring a power current supplied by a main power FET, according to the first embodiment;

FIG. 3 schematically illustrates an example device for measuring a power current supplied by a main power FET, according to a second embodiment;

FIG. 4 schematically illustrates an example device for measuring a power current supplied by a main power FET, according to a third embodiment;

FIG. 5 schematically illustrates an example device for measuring a power current supplied by a main power FET, according to a fourth embodiment;

FIG. 6 schematically illustrates a variant of the device for measuring a power current supplied by a main power FET, according to the fourth embodiment; and

FIG. 7 schematically illustrates the steps in producing a device for measuring a power current supplied by a main power FET.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only the operations and elements useful for understanding the embodiments described herein have been illustrated and described in detail. In particular, the various transistors and the comparator of the device for measuring a power current are not detailed. Those skilled in the art will be able to realize these elements in detail from the functional description given here.

Unless indicated otherwise, when two elements are connected, this signifies a direct connection without intermediate elements other than conductors. When two elements are coupled together, this signifies that these two elements can be connected or coupled via one or more other elements.

Unless specified otherwise, the expressions “around,” “approximately,” “substantially,” and “in the order of” signify within 10% and preferably within 5%.

In all the embodiments described, for each transistor, the first and second source or drain terminals correspond to two mutually different terminals of the same transistor, one corresponding to the source terminal and the other corresponding to the drain terminal.

In relation to FIG. 1, below is described as a first example of a device 100 for measuring a power current supplied by a main power FET 102 according to a first embodiment.

In this first example, the transistor 102 powers an electrical load 104, supplying a load current called “I_load.” For example, electrical load 104 corresponds to a motor, a lamp, or any other electrical element designed to be powered by an electrical power current. The expression “electrical power current,” which applies to the load current supplied by the transistor 102, designates, for example, an electrical current, the intensity of which is between a few milliamperes and several tens of amperes, this value being a function of the size of the transistor 102.

For example, transistor 102 and device 100 form part of a power control circuit 1000, and the other components (converter, regulator, etc.) are not shown in FIG. 1. In the example shown in FIG. 1, the power control circuit 1000 is of the “High Side” type, i.e. corresponds to a power control circuit interposed between the electrical load 104 and the positive electrical supply potential of this electrical load 104. Thus, transistor 102 comprises a first source or drain terminal 106 coupled with an electrical supply potential “+V,” and a second source or drain terminal 108 coupled with a terminal of the electrical load 104 to which the current I_load is supplied. The transistor 102 is designed to receive a signal controlling the power supply to the load 104 on its gate.

In the first example embodiment shown in FIG. 1, the transistor 102 is N-type. Therefore, the first terminal 106 corresponds to the drain of the transistor 102, and the second terminal 108 corresponds to the source of the transistor 102.

Device 100 includes a current-measuring power FET 110 comprising a first source or drain terminal 112 coupled with the first terminal 106 of transistor 102, thus with the electrical supply potential +V. The transistor 110 is designed to receive on its gate the same signal as that applied to the gate of transistor 102. Transistors 102 and 110 are, therefore, switched on or off simultaneously.

In the example embodiment shown in FIG. 1, the transistor 110 is N-type and, therefore, of the same type as the transistor 102. The first terminal 112, therefore, corresponds to the drain of the transistor 110.

Device 100 also includes the first and second FETs, referenced 114 and 116, respectively, which, unlike transistors 102, and 110, are not power transistors. A first source or drain terminal 118 of the transistor 114 is coupled with a second source or drain terminal 120 of the transistor 110, i.e. the source of the transistor 110 in the embodiment described here.

In the example embodiment shown in FIG. 1, a first source or drain terminal 122 of the transistor 116 is coupled with the first terminal 118 of the transistor 114. The transistor 114 also has a second source or drain terminal 124 to which a measurement current called “Isense” is intended to be supplied. The transistor 116 also comprises a second source or drain terminal 126, intended to supply a current whose characteristics are described in greater detail below.

In the example embodiment shown in FIG. 1, the transistors 114, 116 are P-type, so the first terminals 118, 122 correspond to the sources of these transistors 114, 116, and the second terminals 124, 126 correspond to the drains of these transistors 114, 116.

In this first example embodiment, the device 100 also comprises a comparator 128 with a first input 130 coupled with the second terminal 108 of the transistor 102, a second input 132 coupled with the second terminal 120 of the transistor 110, and an output 134 coupled with the gates of transistors 114, 116, which are thus electrically coupled with each other. In this configuration, the voltages VGS of transistors 114, 116 are identical.

Transistors 110, 114, 116 of the device 100 are designed with a semiconductor surface of the transistor 110 and the channel widths of transistors 114, 116 such that the value of a ratio K_target=I_load/Isense is different from that of a ratio Kref between a semiconductor surface of the transistor 102 and the semiconductor surface of the transistor 110.

In the example embodiment shown in FIG. 1, transistors 110, 114 and 116 are dimensioned so that the value of the ratio K_target is greater than that of the ratio Kref between the semiconductor surfaces of the transistors 102 and 110. The transistor 110 therefore outputs, on its second terminal 120, a current Isense_ref=I_load/Kref of greater value than that of the current Isense.

Obtaining the current Isense from the current Isense_ref is made possible by the fact that transistors 114, 116 both receive the current Isense_ref as input at their first terminal 118, 122 and output part of this current Isense_ref at their second terminal 124, 126. The transistor 114 has a channel width called “W1” and the transistor 116 has a channel width called “W2” such that W2=K*W1, with K a real number greater than 0. In the example embodiment shown in FIG. 1, K corresponds to an integer greater than or equal to 1. According to a particular example embodiment, transistors 114, 116 may have channel widths different from each other, which means that the value of K is different from 1, and, for example, greater than 1.

The current Isense supplied to the second terminal 124 of the transistor 114 is therefore such that Isense=I_load/K_target with K_target=Kref*(1+K), and the current supplied to the second terminal 126 of the transistor 116 is therefore equal to K*Isense. These currents satisfy the relationship Isense_ref=(1+K)*Isense.

From the measurement current Isense obtained, and knowing the values of the ratios Kref and K, it is therefore possible to determine the value of the current I_load. Measuring the current Isense and calculating the current I_load may be performed by elements of the device 100 not shown in FIG. 1.

In this way, the transistor 110 is made with a larger semiconductor surface area than would enable the transistor 110 alone, without the presence of transistors 114, 116, to supply the current Isense.

In a particular example embodiment, the current K*Isense supplied to the second terminal 126 of the transistor 116 may be reused for an application other than measuring the current I_load.

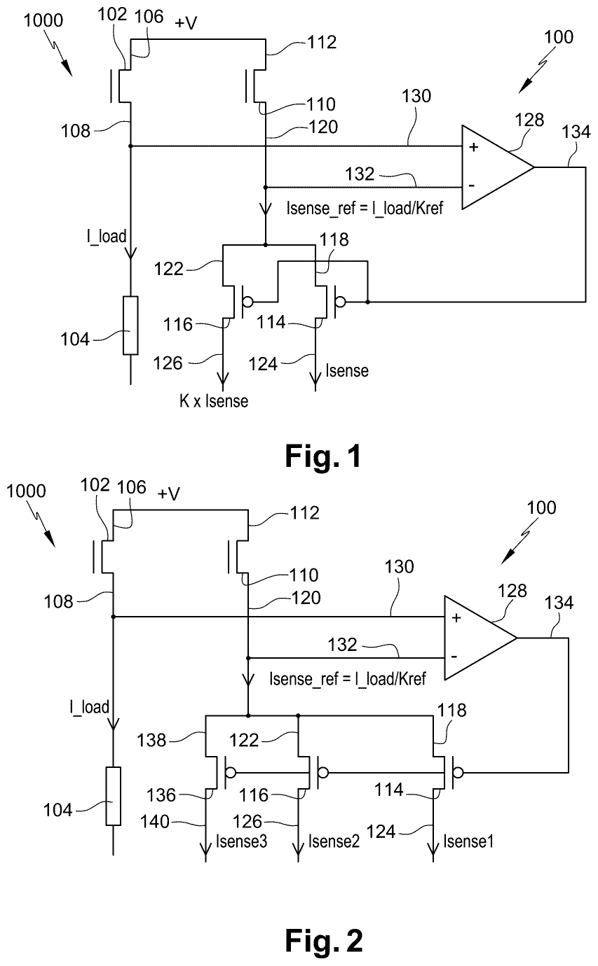

A variant of the device 100 according to the first embodiment is described below in relation to FIG. 2.

The device 100 according to this variant comprises all the elements and components of the device 100 previously described in relation to FIG. 1.

In addition, the device 100 shown in FIG. 2 comprises at least one third FET 136, the gate of which is coupled with the output 134 of comparator 128, and thus also with the gates of transistors 114, 116. A first source or drain terminal 138 of the transistor 136 is coupled with the first terminal 118 of the transistor 114 (which in turn is coupled with the first terminal 122 of transistor 116 and the second terminal 120 of transistor 110).

In the example described here, the transistor 136 is of the same type as transistors 114, 116, i.e. P-type. Thus, the first terminal 138 corresponds to the source of the transistor 136, and the second terminal 140 corresponds to the drain of the transistor 136.

In the variant shown in FIG. 2, the transistors 114, 116, 136 are such that the transistor 114 has a channel width W1 and outputs a current Isense1 at its second terminal 124; the transistor 116 has a channel width W2 and outputs a current Isense2 at its second terminal 126; the transistor 136 has a channel width W3 and outputs a current Isense3 at its second source or drain terminal 140.

In the example shown in FIG. 2, transistors 114, 116, 136 receive the current Isense_ref on their first terminal 118, 122, 138 and output part of this current Isense_ref on their second terminal 124, 126, 140. The currents Isense1, Isense2, and Isense3 supplied to the second terminals 124, 126, 140 of these transistors 114, 116, 136 thus satisfy the following relationships:

$$Isense\_ref = {Isense}_{1} + {Isense}_{2} + {Isense}_{3} ;$$

$${Isense}_{1} = ( {W}_{1} / ( {W}_{1} + {W}_{2} + {W}_{3} ) ) * Isense\_ref ;$$

$${Isense}_{2} = ( {W}_{2} / ( {W}_{1} + {W}_{2} + {W}_{3} ) ) * Isense\_ref ; and$$

$${Isense}_{3} = ( {W}_{3} / ( {W}_{1} + {W}_{2} + {W}_{3} ) ) * Isense\_ref .$$

The different currents Isense1, Isense2 and Isense3 may, for example, be used for different functions: load 104 diagnostics, protection of the electrical harness coupled with the transistor 102, protection against current peaks, etc.

According to another variant, the device 100 could comprise a larger number of FETs comprising their first source or drain terminal coupled with the second terminal 120 of transistor 110 and their second source or drain terminal on which a measurement current is obtained.

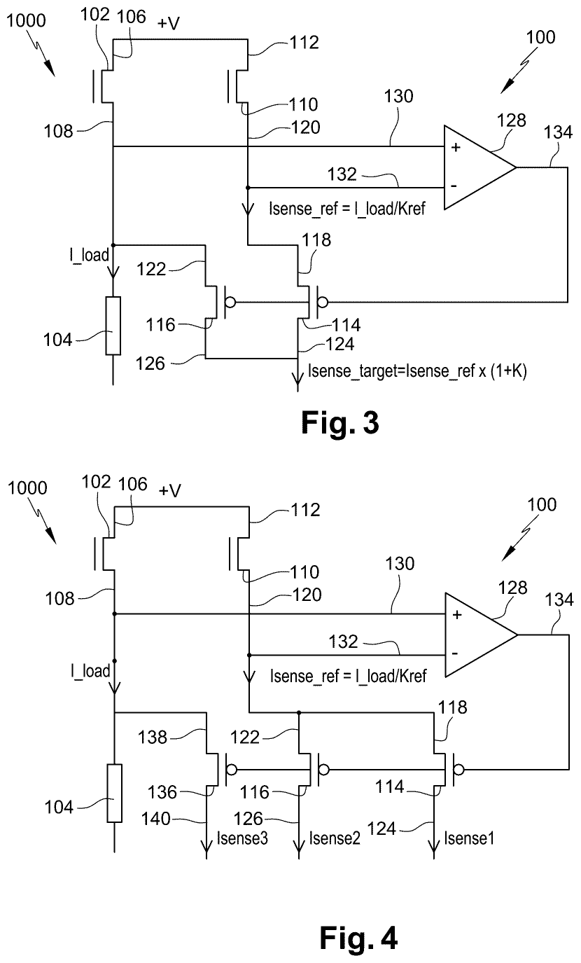

An example device 100 for measuring a power current outputted by the main power FET 102 according to a second embodiment is described below in relation with FIG. 3.

The device 100 according to this second embodiment comprises all the elements and components of the device 100 previously described in relation with FIG. 1.

In contrast to the device 100 according to the first embodiment, the first terminal 122 of the transistor 116 is not coupled with the first terminal 118 of the transistor 114, but to the second terminal 108 of the transistor 102. In addition, the second terminals 124, 126 of transistors 114, 116 are electrically coupled with each other.

Thus, unlike the first embodiment, in which the current Isense supplied by the second transistor 114 is lower than the current Isense_ref supplied by the transistor 110, the current supplied by the second transistor 114 is equal to Isense_ref, to which is added, at the junction of the second terminals 124, 126, the current supplied on the second terminal 126 of the transistor 116. The device 100 according to the second embodiment therefore makes it possible to obtain, at the junction of the second terminals 124, 126 of the transistors 114, 116, a current Isense_target greater than the current Isense_ref outputted by the transistor 110.

In this second embodiment, comparator 128 regulates the current flowing through the transistor 110 so as to have the potential on the second terminal 120 of the transistor 110 similar, or substantially equal, to that on the second terminal 108 of the transistor 102. The potential on the first terminal 118 of the transistor 114 (which is equal to that on the second terminal 120 of the transistor 110) is therefore similar, or substantially equal, to that on the first terminal 122 of the transistor 116 (which is equal to that on the second terminal 108 of the transistor 102). As the voltages VGS of transistors 114, 116 are similar, or substantially equal, due to the presence of the comparator 128, the values of the currents supplied by transistors 114, 116 are therefore proportional to their respective sizes.

Thus, considering the channel width W1 of the transistor 114 and the channel width W2 of the transistor 116, which are such that W2=K*W1, the current Isense_target supplied to the junction of the second terminals 124, 126 of the transistors 114, 116 is such that Isense_target=I_sense_ref*(1+K), since the current supplied to the second terminal 124 of the transistor 114 is equal to Isense_ref and the current supplied to the second terminal 126 of the transistor 116 is equal to K*Isense_ref.

In this second embodiment, because the second terminals 118, 122 of the transistors 114, 116 are not electrically coupled with each other, it is possible that the potentials applied to the second terminals 118, 122 are not perfectly equal. A potential difference, for example equal to a few mV, may therefore appear on the inputs 130, 132 of the comparator 128, resulting in a variation of the current outputted by the transistor 116 with respect to the current outputted by the transistor 114. However, the various components of the device 100 are dimensioned and optimized (in particular the offset of the comparator 128 and the ratio of the dimensions of the transistors 114 and 116) to minimize this possible potential difference as much as possible.

An example of a device 100 for measuring a power current supplied by the main power FET 102 according to a third embodiment is described below in relation with FIG. 4.

The device 100 according to this third embodiment comprises all the elements and components of the device 100 previously described in relation with FIG. 1.

In addition, the device 100 shown in FIG. 4 comprises the third FET 136, the gate of which is coupled with the output 134 of comparator 128, and therefore also with the gates of transistors 114, 116. The first source or drain terminal 138 of the transistor 136 is coupled with the second terminal 108 of the transistor 102.

As in the first embodiment, transistors 114, 116 both receive the current Isense_ref at their first terminal 118, 122, and output part of this current Isense_ref at their second terminal 124, 126. The currents Isense1 and Isense2 supplied to the second terminals 124, 126 of these transistors 114, 116 therefore satisfy the following relationships:

$$Isense\_ref = {Isense}_{1} + {Isense}_{2} ;$$

$${Isense}_{1} = ( {W}_{1} / ( {W}_{1} + {W}_{2} ) ) * Isense\_ref ;$$

$${Isense}_{2} = ( {W}_{2} / ( {W}_{1} + {W}_{2} ) ) * Isense\_ref ; and$$

with W1 corresponding to the channel width of the transistor 114 and W2 corresponding to the channel width of the transistor 116.

The transistor 136 also outputs a current Isense3 proportional to the current I_load at its second terminal 140.

Alternatively, the second terminal 140 of the transistor 136 may be coupled with the second terminal 124, 126 of one of the transistors 114, 116 in order to obtain, at the junction of the two second terminals coupled with each other, a current corresponding to the sum of the current Isense3 with one of the currents Isense1 or Isense2.

Alternatively, the device 100 may comprise one or more further FETs, a first source or drain terminal of which is coupled with the first terminal 118 of the first transistor 114.

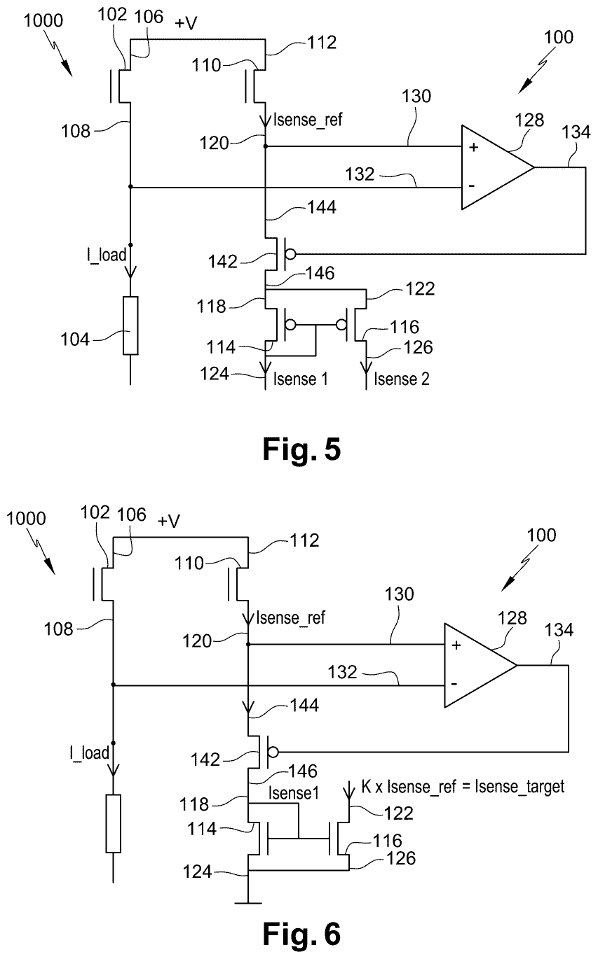

An example of a device 100 for measuring a power current outputted by the main power FET 102 according to a fourth embodiment is described below in relation with FIG. 5.

The device 100 according to this fourth embodiment comprises all the elements and components of the device 100 previously described in relation with FIG. 1.

The device 100 according to this fourth embodiment also comprises another FET 142, a first source or drain terminal 144 of which is coupled with the second terminal of the transistor 110, and a second source or drain terminal 146 of which is coupled with the first terminals 118, 122 of transistors 114, 116, which are electrically coupled with each other. In the example embodiment shown in FIG. 5, the transistor 142 is P-type, with the first terminal 144 corresponding to the source of the transistor 142, and the second terminal 146 corresponding to the drain of the transistor 142.

Unlike the previously described example embodiments, the output 134 of the comparator 128 is not electrically coupled with the gates of the transistors 114, 116, but to the gate of the transistor 142.

Transistors 114, 116 are current mirrored. The gates of transistors 114, 116 are thus electrically coupled with each other and with the second terminal 124 of the transistor 114. A current Isense1 is supplied to the second terminal 124 of the transistor 114 and a current Isense2 is supplied to the second terminal 126 of the transistor 116.

As in the first embodiment, the transistor 114 has a channel width W1, and the transistor 116 has a channel width W2 such that W2=K*W1, with K a real number greater than 0. In the example embodiment shown in FIG. 1, K corresponds to an integer greater than or equal to 1. According to a particular example embodiment, transistors 114, 116 may have channel widths different from each other, meaning that the value of K is different from 1, and for example greater than 1.

As in the first embodiment, transistors 114, 116 both receive the current Isense_ref at their first terminal 118, 122, and output part of this current Isense_ref at their second terminal 124, 126. The currents Isense1 and Isense2 supplied to the second terminals 124, 126 of these current-mirror transistors 114, 116 thus satisfy the following relationships:

$$Isense\_ref = {Isense}_{1} + {Isense}_{2} ;$$

$${Isense}_{1} = ( {W}_{1} / ( {W}_{1} + {W}_{2} ) ) * Isense\_ref ; and$$

$${Isense}_{2} = ( {W}_{2} / ( {W}_{1} + {W}_{2} ) ) * Isense\_ref .$$

A variant of the device 100 according to the fourth embodiment is described below in relation with FIG. 6. The device 100 according to this variant comprises all the elements and components of the device 100 previously described in relation with FIG. 5. However, in the device 100 shown in FIG. 6, the transistors 114, 116 (current mirrored) are N-type, their first terminal 118, 122 corresponding to the drain, and their second terminal 124, 126 corresponding to the source of these transistors 114, 116. The gates of transistors 114, 116 are electrically coupled with each other and to the first terminal 118 of the transistor 114. The first terminal 122 of the transistor 116 is coupled with a voltage source or load (not visible in FIG. 6) capable of supplying a current K*Isense_ref to the first terminal 122 of the transistor 116. The second terminals 124, 126 of transistors 114, 116 are electrically coupled with each other.

In this variant, the current Isense_target is equal to the current K*Isense_ref flowing in the first terminal 122 of the transistor 116, and the current Isense1 flowing in the first terminal 118 of the transistor 114 is equal to the current Isense_ref. As in previous examples, the transistor 114 has a channel width W1, and the transistor 116 has a channel width W2 such that W2=K*W1.

In all the above-described embodiments, examples, and variants, the current measurement accuracy achieved by the device 100 is, for example, less than or equal to 5% of the nominal value of the current I_load, throughout the operating temperature range of the device 100.

The proposed circuit makes it possible to use a current-measurement power FET of larger dimensions than existing solutions, and thus avoids the problems encountered with a transistor of too small dimensions, such as differences in dynamic behavior compared with that expected, or a change in the response of the measurement transistor as a function of operating temperature, the effects of which would be similar to a change in the value of the ratio K_target as a function of operating temperature. The behavior of the current-measuring power FET is also closer to that of the main power FET, whatever the values of external parameters such as temperature or the voltages V_{GS} applied to these transistors.

In all embodiments, examples and variants, the transistors are sized according to the desired values of the various ratios K_target, Kref, and K, themselves being a function of the features and functionalities of the electrical environment in which the device 100 and the circuit 1000 are used. For example, the value of the ratio K_target (which may be set according to the application of the device 100) may be greater than or equal to 1000, or for example to one of the following values: 1,000, 2,000, 10,000, 40,000. For example, the value of the ratio K_target may be 4 to 10 times greater than that of the ratio Kref.

In all embodiments, examples and variants, the main power FET 102 and the current-measuring power FET may be, for example, VDMOSFETs (Vertical Double Diffused Metal-Oxide-Semiconductor Field-Effect Transistor).

In all embodiments, examples and variants, the FETs 114, 116, 136, 142 may be, for example, MOSFET-type transistors. In addition, these FETs 114, 116, 136, 142 may be N- or P-type transistors.

In all embodiments, examples and variants, the FETs 114, 116, 136, 142 form an output stage allowing the desired ratio of measurement current to load current to be obtained at the output.

In all embodiments and variants, the main power FET 102 and/or the current measurement power FET 110 are of the same N- or P-type.

As an alternative to the example embodiments described above, the transistor 102 and the device 100 may form part of a “low-side” power control circuit 1000, i.e. a control circuit interposed between the electrical load 104 and the electrical reference potential of this electrical load 104. In this case, the first terminals of the power transistors 102, 110 are not coupled with the supply terminal potential but to one of the terminals of the electrical load 104, and the second terminal 108 of the transistor 102 is coupled with the reference electrical potential.

The measurement device 100 and the control circuit 1000 may be designed as independent modules, or may be integrated into chips, or integrated circuits with other functions, e.g. using technology integrating power components and CMOS components, and/or bipolar (analog), CMOS (digital) and DMOS (Double-Diffused MOS, being power components) components.

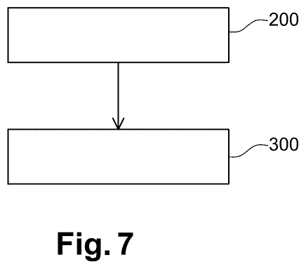

FIG. 7 schematically illustrates the steps in an example method for manufacturing the power control circuit 1000 for controlling the electrical load 104.

In a first step 200, the semiconductor area of the transistor 110 and the channel widths of transistors 114, 116 are determined such that the value of the ratio K_target between load current I_load and output current Isense is different from that of the ratio Kref between the semiconductor area of the transistor 102 and the semiconductor area of the transistor 110. In this step, any other elements or components of the device 100 are also sized according to the desired features of the device 100.

In a step 300, the main power FET 102 and the various components of the device 100 are then formed. In particular, transistors 110, 114, and 116 are formed in accordance with the previously determined surface areas and channel widths.

The measurement device 100 and the control circuit 1000 may be advantageously applied to the automotive field, for example in an electrical power distribution and management circuit of a vehicle. The measurement device 100 and the control circuit 1000 can also be used in other fields, for example in industry.

In embodiments, a current path terminal refers to a source terminal, a drain terminal, or both of a FET.

Various embodiments and variants have been described. Those skilled in the art will understand that certain features of these embodiments may be combined and other variants will readily occur to those skilled in the art.

Finally, the practical implementation of the embodiments and variants described herein is within the capabilities of those skilled in the art based on the functional description provided hereinabove.

What is claimed is:

1. A device for measuring a power current to be supplied by a main power field effect transistor (FET), the device comprising:
a current measurement power FET comprising a first current path terminal couplable to a first current path terminal of the main power FET; and
a first FET and a second FET, wherein a gate terminal of the first FET is electrically coupled to a gate terminal of the second FET,
wherein a first current path terminal of the first FET is coupled to a second current path terminal of the current measurement power FET, or
wherein a first current path terminal of the second FET is coupled to the first current path terminal of the current measurement power FET, a second current path terminal of the main power FET, a voltage source, or a load external to the device, and a second current path terminal of the first FET is electrically coupled to a second current path terminal of the second FET.

2. The device of claim 1, wherein a semiconductor surface of the current measurement power FET and channel widths of the first FET and the second FET are such that a ratio between a charging current to be supplied at the second current path terminal of the main power FET and an output current to be supplied at the second current path terminal of the first FET differs from a ratio between a semiconductor surface of the main power FET and the semiconductor surface of the current measurement power FET.

3. The device of claim 1, wherein the current measurement power FET is of a vertical double-diffused metal-oxide-semiconductor FET (VDMOSFET) type, and wherein the first FET and second FET are of a MOSFET type.

4. The device of claim 1, wherein channel widths of the first FET and the second FET are different.

5. The device of claim 1, further comprising a comparator having a first input couplable to the second current path terminal of the main power FET, a second input of the comparator couplable to the second current path terminal of the current measurement power FET, and an output of the comparator couplable to the gate terminal of the first FET and the gate terminal of the second FET.

6. The device of claim 1, further comprising a third FET, wherein a gate terminal of the third FET is coupled to the gate terminal of the first FET and the gate terminal of the second FET, and wherein a first current path terminal of the third FET is coupled to the first current path terminal of the first FET or the second current path terminal of the main power FET.

7. The device of claim 1, further comprising:
a fourth FET, wherein a first current path terminal of the fourth FET is coupled to the second current path terminal of the current measurement power FET, and a second current path terminal of the fourth FET is coupled to the first current path terminal of the first FET; and
a comparator having a first input coupled to the second current path terminal of the current measurement power FET, a second input of the comparator couplable to the second current path terminal of the main power FET, and an output of the comparator coupled to a gate terminal of the fourth FET.

8. The device of claim 7, wherein the first FET and the second FET are arranged as a current mirror.

9. The device of claim 8, wherein the first FET and the second FET are P-type, wherein the gate terminal of the first FET and the gate terminal of the second FET are coupled to the second current path terminal of the first FET, and wherein the first current path terminal of the second FET is coupled to the first current path terminal of the first FET.

10. The device of claim 8, wherein the first FET and the second FET are N-type, wherein the gate terminal of the first FET and the gate terminal of the second FET are coupled to the first current path terminal of the first FET, and wherein the second current path terminal of the first FET and the second current path terminal of the second FET are electrically coupled.

11. A power control circuit for controlling an electrical load, the power control circuit comprising:
a main power field effect transistor (FET) comprising a first current path terminal couplable to an electrical power source, a second current path terminal of the main FET couplable to a terminal of the electrical load; and
a measurement circuit configured to measure a power current to be supplied by the main FET, the measurement circuit comprising:
a current measurement power FET comprising a first current path terminal couplable to a first current path terminal of the main power FET; and
a first FET and a second FET, wherein a gate terminal of the first FET is electrically coupled to a gate terminal of the second FET,
wherein a first current path terminal of the first FET is coupled to a second current path terminal of the current measurement power FET, or
wherein a first current path terminal of the second FET is coupled to the first current path terminal of the current measurement power FET, a second current path terminal of the main power FET, a voltage source, or the electrical load, and a second current path terminal of the first FET electrically coupled to a second current path terminal of the second FET.

12. The power control circuit of claim 11, wherein the main power FET and the current measurement power FET are of a same conductivity type.

13. The power control circuit of claim 11, wherein a semiconductor surface of the current measurement power FET and channel widths of the first FET and the second FET are such that a ratio between a charging current to be supplied at the second current path terminal of the main power FET and an output current to be supplied at the second current path terminal of the first FET differs from a ratio between a semiconductor surface of the main power FET and the semiconductor surface of the current measurement power FET.

14. The power control circuit of claim 11, wherein the measurement circuit further comprises a comparator having a first input couplable to the second current path terminal of the main power FET, a second input of the comparator couplable to the second current path terminal of the current measurement power FET, and an output of the comparator couplable to the gate terminal of the first FET and the gate terminal of the second FET.

15. A method to measure a power current to be supplied by a main power field effect transistor (FET) in a device, the method comprising:
receiving a control signal at a gate terminal of a current measurement power FET, the gate terminal of the current measurement power FET is coupled to a gate terminal of the main FET, and a first current path terminal of the current measurement power FET coupled to a first current path terminal of the main power FET; and
regulating, by a comparator, a first potential at a second terminal of the current measurement power FET to equal a second potential at a second terminal of the main FET, wherein a gate terminal of a first FET is electrically coupled to a gate terminal of a second FET,
wherein a first current path terminal of the first FET is coupled to a second current path terminal of the current measurement power FET, or
wherein a first current path terminal of the second FET is coupled to the first current path terminal of the current measurement power FET, a second current path terminal of the main power FET, a voltage source, or an external electrical load, and a second current path terminal of the first FET electrically coupled to a second current path terminal of the second FET.

16. The method of claim 15, wherein a semiconductor surface of the current measurement power FET and channel widths of the first FET and the second FET are such that a ratio between a charging current to be supplied at the second current path terminal of the main power FET and an output current to be supplied at the second current path terminal of the first FET differs from a ratio between a semiconductor surface of the main power FET and the semiconductor surface of the current measurement power FET.

17. The method of claim 15, wherein the comparator includes a first input coupled to the second current path terminal of the main power FET, a second input of the comparator is coupled to the second current path terminal of the current measurement power FET, and an output of the comparator is coupled to the gate terminal of the first FET and the gate terminal of the second FET.

18. The method of claim 15, wherein a gate terminal of a third FET is coupled to the gate terminal of the first FET and the gate terminal of the second FET, and wherein a first current path terminal of the third FET is coupled to the first current path terminal of the first FET or the second current path terminal of the main power FET.

19. The method of claim 15, wherein the current measurement power FET is of a vertical double-diffused metal-oxide-semiconductor FET (VDMOSFET) type, and wherein the first FET and second FET are of a MOSFET type.

20. The method of claim 15,
wherein the first FET and the second FET are P-type, wherein the gate terminal of the first FET and the gate terminal of the second FET are coupled to the second current path terminal of the first FET, and wherein the first current path terminal of the second FET is coupled to the first current path terminal of the first FET, or
wherein the first FET and the second FET are N-type, wherein the gate terminal of the first FET and the gate terminal of the second FET are coupled to the first current path terminal of the first FET, and wherein the second current path terminal of the first FET and the second current path terminal of the second FET are electrically coupled.
